(19) United States
(12) Patent Application Publication
(10) Pub. No.: US 2015/0042165 A1
(43) Pub. Date: Feb. 12, 2015

(54) POWER MANAGEMENT CIRCUIT

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: BO TIAN, Shenzhen (CN); KANG WU, Shenzhen (CN)

(21) Appl. No.: 14/458,217

(22) Filed: Aug. 12, 2014

(30) Foreign Application Priority Data
Aug. 12, 2013 (CN) 2013103482459

(51) Int. Cl. H05K 7/14; G05B 11/01; H02J 4/00

(52) U.S. Cl. CPC H05K 7/1492; H02J 4/00; G05B 11/01
USPC 307/52

(57) ABSTRACT

A power management circuit includes a system connector, first and second power connectors, and a control chip. The system connector is used to connect a main server of a server system. The first power connector is used to connect a first power source and the second power connector is used to connect a second power source. The control chip is coupled to the system connector, the first power connector, and the second power connector. The control chip converts signals from the main server into control signals to the first and second power sources. The control chip processes signals from the first and second power sources and outputs the processed signals to the main server.

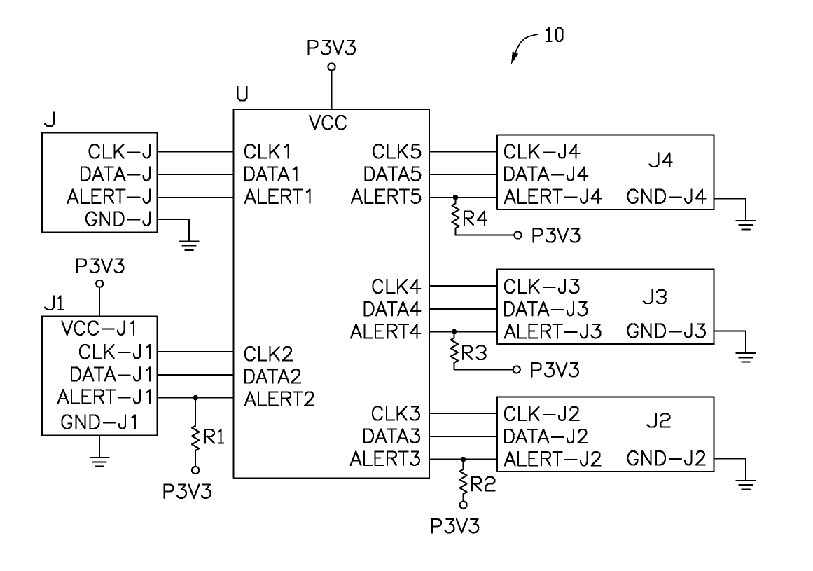

### FIELD

The present disclosure relates to a power management circuit.

### BACKGROUND

Power sources need to operate with a power management circuit.

### BRIEF DESCRIPTION OF THE DRAWING

Implementations of the present technology will now be described, by way of example only, with reference to the attached figure.

The FIGURE is a circuit diagram of an embodiment of a power management circuit.

### DETAILED DESCRIPTION

Numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” when utilized, means “including, but not necessarily limited to”; it specifically indicates open-ended inclusion or membership in the so-described combination, group, series and the like.

The FIGURE shows an embodiment of a power management circuit (power management circuit 10).

The power management circuit 10 can comprise a system connector J, a first power connector J1, a second power connector J2, a third power connector J3, a fourth power connector J4, and a control chip U. The system connector J is configured to be coupled to a main server of a server system. The first power connector J1 is coupled to a first power source. The second power connector J2 is coupled to a second power source. The third power connector J3 is coupled to a third power source. The fourth power connector J4 is coupled to a fourth power source.

A first clock pin CLK1 of the control chip U, a first data pin DATA1 of the control chip U, and a first alarm pin ALERT1 of the control chip U are respectively coupled to a clock pin CLK_J of the system connector J, a data pin DATA_J of the system connector J, and an alarm pin ALERT_J of the system connector J. A second clock pin CLK2 of the control chip U, a second data pin DATA2 of the control chip U, and a second alarm pin ALERT2 of the control chip U are respectively coupled to a clock pin CLK_J1 of the first power connector J1, a data pin DATA_J1 of the first power connector J1, and an alarm pin ALERT_J1 of the first power connector J1. A third clock pin CLK3 of the control chip U, a third data pin DATA3 of the control chip U, and a third alarm pin ALERT3 of the control chip U are respectively coupled to a clock pin CLK_J2 of the second power connector J2, a data pin DATA_J2 of the second power connector J2, and an alarm pin ALERT_J2 of the second power connector J2. A fourth clock pin CLK4 of the control chip U, a fourth data pin DATA4 of the control chip U, and a fourth alarm pin ALERT4 of the control chip U are respectively coupled to a clock pin CLK_J3 of the third power connector J3, a data pin DATA_J3 of the third power connector J3, and an alarm pin ALERT_J3 of the third power connector J3. A fifth clock pin CLK5 of the control chip U, a fifth data pin DATA5 of the control chip U, and a fifth alarm pin ALERTS of the control chip U are respectively coupled to a clock pin CLK_J4 of the fourth power connector J4, a data pin DATA_J4 of the fourth power connector J4, and an alarm pin ALERT_J4 of the fourth power connector J4. A power pin VCC of the control chip U is coupled to a power terminal P3V3. A ground pin GND_J of the system connector J is grounded. A ground pin GND_J1 of the first power connector J1 is grounded. A power pin VCC_J1 of the first power first power connector J1 is coupled to the power terminal P3V3. A ground pin GND_J2 of the second power connector J2 is grounded. A power pin VCC_J2 of the second power connector J2 is coupled to the power terminal P3V3. A ground pin GND_J3 of the third power connector J3 is grounded. A power pin VCC_J3 of the third power connector J3 is coupled to the power terminal P3V3. A ground pin GND_J4 of the fourth power connector J4 is grounded. A power pin VCC_J4 of the fourth power connector J4 is coupled to the power terminal P3V3.

The control chip U is configured to convert signals from the main server into control signals to the first through fourth power sources. The control chip also processes signals from the first through fourth power sources and outputs signals after processing to the main server.

In use, to monitor a status of the first power source, the main server outputs a first signal to the control chip U through the system connector J. The control chip U converts the first signal into a first control signal and outputs the first control signal to the first power source. The first power source outputs a first status signal to the control chip U when the first power source receives the first control signal. The control chip U transmits the first status signal to the main server. The main server can obtain respective statuses of other power sources similarly. The main server outputs the first signal to the clock pin CLK J of the system connector J and the data pin DATA_J of the system connector J. The control chip U outputs the first control signal through the second clock pin CLK_J2 of the control chip U and the second data pin DATA_J2 of the control chip U.

When one of the power sources (eg. the first power source) operates abnormally, the first power source outputs a first alarm signal to the second alarm pin ALERT2 of the control chip U through the alarm pin ALERT_J1 of the first power connector J1. The control chip processes the first alarm signal and outputs the processed first alarm signal to the main server through the first alarm pin ALERT1. The main server can obtain alarm signals of other power sources similarly.

What is claimed is:

1. A power management circuit comprising:
a system connector configured to connect a main server of a server system;
a first power connector configured to be coupled to a first power source and a second power connector configured to be coupled to a second power source; and
a control chip coupled to the system connector, the first power connector, and the second power connector;
wherein the control chip is configured to convert signals transmitted from the main server into control signals, transmit the control signals to the first and second power sources, process signals from the first and second power sources, and output the processed signals to the main server.

2. The power management circuit of claim 1, wherein a first clock pin of the control chip is coupled to a clock pin of the system connector, a first data pin of the control chip is coupled to a data pin of the system connector, a second clock pin of the control chip is coupled to a clock pin of the first power connector, a second data pin of the control chip is coupled to a data pin of the first power connector, a third clock pin of the control chip is coupled to a clock pin of the second power connector, and a third data pin of the control chip is coupled to a data pin of the second power connector.

3. The power management circuit of claim 1, further comprising a third power connector and a fourth power connector, wherein the third power connector is configured to be coupled to a third power source, the fourth power connector is configured to be coupled to a fourth power source, and the control chip processes signals from the third and fourth power sources and outputs the processed signals to the main server.

4. The power management circuit of claim 2, wherein the control chip further comprises a first alarm pin, a second alarm pin, and a third alarm pin, the first alarm pin of the control chip is coupled to an alarm pin of the system connector, the second alarm pin of the control chip is coupled to an alarm pin of the first power connector, and the third alarm pin of the control chip is coupled to an alarm pin of the second power connector.

5. The power management circuit of claim 3, wherein the control chip further comprises a fourth alarm pin and a fifth alarm pin, the fourth alarm pin of the control chip is coupled to an alarm pin of the third power connector, and the fifth alarm pin of the control chip is coupled to an alarm pin of the fourth power connector.
